(19) United States
(12) Patent Application Publication
(10) Pub. No.: US 2022/0230901 A1
(43) Pub. Date: Jul. 21, 2022

(54) CONTAINERS FOR PROTECTING SEMICONDUCTOR DEVICES AND RELATED METHODS

(71) Applicant: Micron Technology, Inc., Boise, ID (US)

(72) Inventors: Mohamed A. Ditali, Boise, ID (US); Andrew F. Laforge, Boise, ID (US); Michael D. Leavitt, Melba, ID (US); Anthony D. Veches, Boise, ID (US)

(21) Appl. No.: 17/248,344

(22) Filed: Jan. 21, 2021

(51) Int. Cl. H01L 21/673; B65D 81/30; B65D 85/30

(52) U.S. Cl. CPC H01L 21/67393; H01L 21/67356; B65D 85/30; H01L 21/67383; B65D 81/30; H01L 21/67366

(57) ABSTRACT

Containers for supporting one or more semiconductor devices therein may include walls positioned to at least partially surround a semiconductor device. At least one of the walls may include a radiation-shielding material. A support structure may be shaped, positioned, and configured to support the semiconductor device within the walls.

### FIELD

This disclosure relates generally to containers (e.g., housings) for semiconductor devices. More specifically, disclosed embodiments relate to containers that may reduce the likelihood that at least some types of radiation (e.g., neutron radiation, proton radiation) may otherwise produce deleterious effects in semiconductor devices, such as, for example, bit flipping in memory devices and/or radiation-induced alteration of current-voltage characteristics of trench FET commercial power MOSFETS.

### BACKGROUND

Shielding materials may conventionally be deployed to contain harmful radiation, such as neutron radiation, within the environment where a radiation source is located. For example, shielding materials may be interposed between a nuclear fuel source and any people or sensitive equipment to reduce the likelihood that radiation emitted by the nuclear fuel source would irradiate those people or sensitive equipment. The shielding materials may at least substantially contain the radiation within an enclosed space defined by the shielding materials.

### BRIEF DESCRIPTION OF THE DRAWINGS

While this disclosure concludes with claims particularly pointing out and distinctly claiming specific embodiments, various features and advantages of embodiments within the scope of this disclosure may be more readily ascertained from the following description when read in conjunction with the accompanying drawings. In the drawings:

FIG. 1 is a cross-sectional side view of a schematic of a container for supporting one or more semiconductor devices therein;

FIG. 2 is a flowchart of a method of protecting one or more semiconductor devices utilizing a container in accordance with this disclosure;

FIG. 3 is an exploded view of another embodiment of a container including a support structure for supporting semiconductor devices within the container;

FIG. 4 is an exploded view of another embodiment of a container including a support structure for supporting semiconductor devices within the container;

FIG. 5 is an exploded view of another embodiment of a container including a support structure for supporting semiconductor devices within the container;

FIG. 6 is a side perspective, transparent view of another embodiment of a container for protecting one or more semiconductor devices therein;

FIG. 7 is a front view of another embodiment of a container for supporting one or more semiconductor devices therein; and

FIG. 8 is a flowchart of a method of making a container for supporting one or more semiconductor devices therein.

### DETAILED DESCRIPTION

It has been established that certain types of radiation, for example, neutron and proton radiation, may cause degradation of semiconductor devices. For example, certain semiconductor-based components of integrated circuits are more or less susceptible to neutron-induced performance degradation. Included are such component devices as bipolar transistors, JFETs, MOSFETS, diodes, operational amplifiers, voltage comparators, TTL and EDL gates, and CMOS gates and, of course, integrated circuits including combinations of such component devices.

Radiation damage mechanisms include two primary types: displacement damage and ionization damage. The former occurs when incident radiation displaces semiconductor (e.g., silicon) atoms from their sites in the silicon lattices, altering electronic characteristics of the crystal. The latter occurs when energy absorbed by electronic ionization in insulating layers, such as SiO₂, liberates charge carriers which, in turn, diffuse or drift to other locations where they are trapped and lead to concentrations of charge and parasitic fields.

While it has been proposed to fabricate integrated circuits from component devices and combinations of component devices configured for radiation resistance, such approaches limit the utility of such circuits and drive up complexity and cost. Other conventional approaches to radiation shielding involve relatively thick, bulky and heavy shielding materials such as concrete or lead, which approaches are impractical if not impossible for many applications where radiation-induced degradation is of concern.

Disclosed embodiments relate generally to containers that may reduce the likelihood that at least some types of radiation may otherwise produce deleterious effects in semiconductor devices. For example, containers in accordance with this disclosure may be positioned, and may have sufficient radiation shielding characteristics, to reduce (e.g., eliminate) the likelihood that radiation from outside the containers will induce damage in semiconductor devices located at least partially within the containers. More specifically, containers in accordance with this disclosure may have one or more panels including radiation absorbing and/or reflecting material in sufficient quantities to inhibit radiation (e.g., proton and/or neutron radiation) at an exterior of the container from passing through the relevant panel to the interior of the container. As a specific, nonlimiting example, containers of this disclosure may reduce (e.g., eliminate) radiation-induced bit flipping in memory devices and radiation-induced alteration of current-voltage characteristics of trench FET commercial power MOSFETS.

In some embodiments, the containers for supporting semiconductor devices in accordance with this disclosure may be configured as storage containers, shipping containers, housings for installed configurations, server racks, and building constructions that may at least partially enclose semiconductor devices. The containers may include shielding materials positioned to reduce or eliminate the likelihood that radiation from the ambient environment exterior to a container will enter a volume where the semiconductor devices are located. For example, the shielding materials may be incorporated into one or more walls of a housing at least partially enclosing semiconductor devices during storage, shipping, and potentially when installed in a system. As another example, the shielding materials may be incorporated into one or more walls of a server rack supporting the semiconductor devices, or into one or more construction materials for the building housing the semiconductor devices. Providing shielding materials at least partially around semiconductor devices may reduce the likelihood that radiation (e.g., neutron radiation) may flip any bits in memory devices (e.g., dynamic random access memory (DRAM)) or induce alteration of current-voltage characteristics of trench FET commercial power MOSFETS. Such a reduction in the phenomenon of radiation-induced bit flipping and/or other radiation-induced damage in semiconductor devices may reduce the error rate in operating semiconductor devices, and reduce the need to re-test and verify the functionality of semiconductor devices after shipping and after spending time in storage.

As used herein, the terms “substantially” and “about” in reference to a given parameter, property, or condition means and includes to a degree that one of ordinary skill in the art would understand that the given parameter, property, or condition is met with a degree of variance, such as within acceptable manufacturing tolerances. For example, a parameter that is substantially or about a specified value may be at least about 90% the specified value, at least about 95% the specified value, at least about 99% the specified value, or even at least about 99.9% the specified value.

The term “semiconductor device,” as used herein, means and includes microelectronic devices formed utilizing doped regions of a semiconducting material. For example, semiconductor devices include processors, memory devices, and systems on a chip, and may be provided in the form of a singulated device region of a semiconductor wafer.

The term “semiconductor wafer,” as used herein, means and includes substrates including semiconducting material. For example, semiconductor wafers may include bulk wafers of undoped semiconducting material or device wafers having discrete regions of doped semiconducting material forming device regions separated by streets, forming a grid.

The term “semiconductor device package,” as used herein, means and includes a semiconductor device in the form of a singulated device region of a semiconductor wafer having protective material surrounding at least a portion of the semiconductor device and an interface structure for integrating the semiconductor device package with higher level packaging. For example, semiconductor device packages include encapsulated semiconductor chips having input and output structures (e.g., pads, balls, bumps, pillars, columns, lead fingers) of electrically conductive material, and may be supported on, and electrically connected to, higher level packaging (e.g., a printed circuit board (PCB), a bread board).

The terms “memory” and “memory device,” as used herein, include microelectronic devices exhibiting, but not limited to, memory functionality, but exclude embodiments encompassing transitory signals. For example, a system on a chip (SoC) is encompassed in the meaning of “memory device.” By way of non-limiting example, memory devices may generally include packaged semiconductor devices having shielding material configurations as described herein, unless otherwise specified.

The illustrations presented in this disclosure are not meant to be actual views of any particular container, semiconductor device, support structure, or component thereof, but are merely idealized representations employed to describe illustrative embodiments. Thus, the drawings are not necessarily to scale.

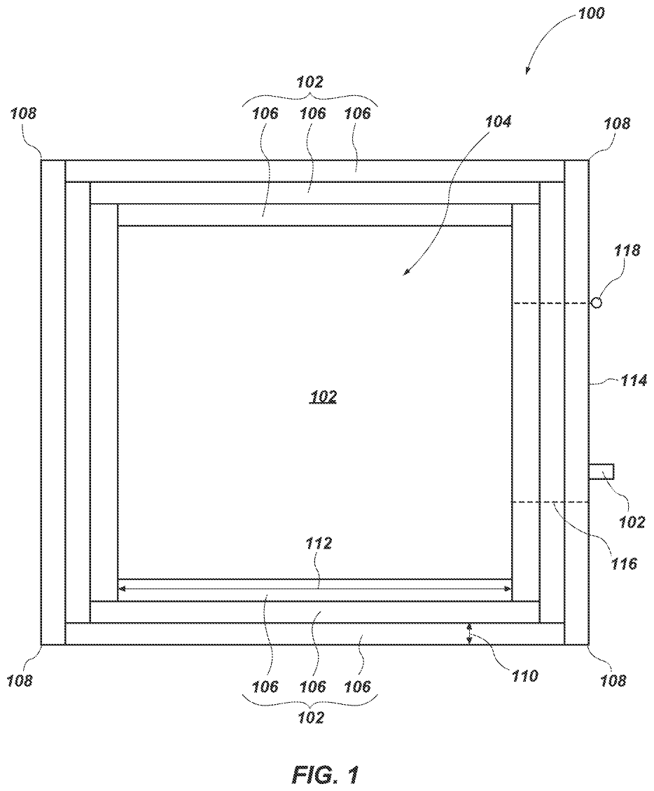

FIG. 1 is a cross-sectional side view of a schematic of a container 100 for supporting one or more semiconductor devices therein. For example, the container 100 may be configured as a box, crate, case, housing, enclosure, rack, room, or building sized, shaped, and otherwise configured to support one or more semiconductor devices at least partially therein. The container 100 may be employed to support the one or more semiconductor devices during, for example, shipping, transport, temporary storage, long-term storage, installed operation.

The container 100 may include, for example, walls 102 sized, shaped, and positioned to at least partially surround a semiconductor device within the container. Though the container 100 shown in FIG. 1 is generally shaped as a rectangular prism, the container 100 may exhibit any shape suitable for a given application. For example, the container 100 may take on another geometrical prismatic shape, may have a shape combining various intersecting geometrical prisms, may include one or more cutouts, may include one or more sloped and/or curved surfaces, or may be an irregular, customized shape (e.g., to accommodate a specific layout or space constraint). The walls 102 may define an interior volume 104 in which at least a portion of at least one semiconductor device may be received. In some embodiments, the walls 102 may fully enclose the interior volume 104, at least when the container 100 is in a closed state. In other embodiments, the interior volume 104 may be in fluid communication with an exterior of the container 100 through an opening, aperture, or port in one or more of the walls 102, even when the container 100 is in a closed state.

At least one of the walls 102 may include a radiation-shielding material. For example, those walls 102 to be positioned between relevant portions of any semiconductor devices at least partially supported within the walls 102 and a source of radiation may include the radiation-shielding material. More specifically, those walls 102 intended for positioning above any semiconductor devices, laterally proximate to any semiconductor devices, and optionally below any semiconductor devices at least partially supported within the container 100 may include or be formed from a radiation-shielding material. As specific, nonlimiting examples, each of the walls 102 may include the radiation-shielding material, or each of the walls 102 other than a wall 102 positioned and configured to face a floor when the container 100 is placed on the floor may include the radiation-shielding material, and the wall 102 positioned to face the floor may lack the radiation-shielding material.

The radiation-shielding material of the wall 102 or walls 102 may be configured to reduce the likelihood that certain types of radiation will alter a state of a silicon lattice in any semiconductor devices supported within the container 100. For example, the radiation-shielding material of the wall 102 or walls 102 may be configured to inhibit one or more types of radiation (e.g., neutron radiation, proton radiation) from altering the state of the silicon lattice in any of the semiconductor devices within the walls 102 in a way that would affect the operation, reliability, or longevity of the semiconductor devices. More specifically, the radiation-shielding material of a given wall 102 may be configured to absorb, deflect, reflect, and/or otherwise mitigate radiation of one or more types (e.g., neutron radiation, proton radiation) to reduce the risk of radiation-induced damage in semiconductor devices (e.g., bit flipping in memory devices, radiation-induced alteration of current-voltage characteristics of trench FET commercial power MOSFETS) within the walls 102 of the container 100.

The radiation-shielding material may be or include, for example, low atomic number elements having scattering cross sections or elements having capturing cross sections. More specifically, the radiation-shielding material may be or include hydrogen, carbon, oxygen, lead, bismuth, tungsten, boron, cadmium, and/or gadolinium. As specific, nonlimiting examples, the radiation-shielding material may be or include at least one material selected from the group consisting of borated polyethylene, boron carbide (e.g., B₄C), a boron aluminum alloy. In embodiments where the container 100 is used for shipping, borated polyethylene may be particularly suitable at least in part because of its lower density than other radiation-shielding materials, resulting a lower-weight container 100 with suitable radiation shielding capabilities.

In some embodiments, one or more of the walls 102 may include multiple sheets 106 of, or including, the radiation-shielding material. For example, two or more sheets 106 may be provided in layers to form at least a portion of at least one of the walls 102 of the container 100. More specifically, at least some, and up to each, of the walls 102 intended to provide radiation shielding capabilities to the container 100 may include two or more of the sheets 106 (e.g., 2, 3, 4, etc.) mutually secured to one another to form the respective wall 102. Providing the radiation-shielding material in sheets 106 may enable selective deployment of a desired level of radiation shielding by adding or removing layers of the sheets 106 when forming the associated wall 102. In other embodiments, one or more of the walls 102 may include a single sheet 106 of or including the radiation-shielding material, and the degree of radiation shielding may be altered by modifying the thickness 110 of the sheet 106, as measured in a direction parallel to a shortest distance between the interior volume 104 and the exterior of the container 100. Suitable sheets 106 including or of radiation-shielding materials are commercially available from, for example, MarShield Custom Radiation Shielding Products of 4140 Morris Dr., Burlington, Ontario, L7L 5L6, Canada, and Apex Industries of 12670 SW Hall Blvd, Igard, Oreg. 97223, USA.

A degree of radiation shielding provided by a given wall 102 of the container 100 may be sufficient to inhibit radiation of certain types of radiation at an exterior of the container 100 from passing through the relevant wall 102 to the interior of the container 100. For example, a quantity of the radiation-shielding material in the wall 102 may be between about 1% and 20% by weight of the wall 102, and a thickness of the wall 102, as measured in a shortest direction from the exterior of the container 100 to the interior, may be between about 0.5 inch and about 12 inches. More specifically, the wall 102 may include between about 1.5% and about 15% by weight of a radiation-shielding element, and the thickness of the wall 102 may be between about 1 inch and about 6 inches. As a specific, nonlimiting example, the wall 102 may include between about 2% and about 10% (e.g., about 5%) boron by weight (e.g., in the form of borated polyethylene), and the thickness of the wall 102 may be between about 2 inches and about 5 inches (e.g., about 3 inches). When compared to enclosures that may be used to contain radiation within the enclosure, rather than keeping environmental radiation out of the container 100, containers 100 in accordance with this disclosure may include thinner walls 102. This comparative thinness may enable the containers 100 to be used in a greater variety of situations, such as, for example, during shipping, short-term storage, medium- to long-term storage, and in installed, operating configurations.

A weight of the container 100 may be low, particularly when compared to enclosures that may be used to contain radiation within the enclosure. For example, the container 100 may weigh about 100 pounds or less. More specifically, the container 100 may weigh between about 1 pound and about 25 pounds. As a specific, nonlimiting example, the container 100 may weigh between about 2 pounds and about 15 pounds (e.g., about 5 pounds, about 10 pounds). This comparative lightness may similarly enable the containers 100 to be used in a greater variety of situations, such as, for example, during shipping, short-term storage, medium- to long-term storage, and in installed, operating configurations.

In some of the embodiments where the walls 102 include adjacent sheets 106 of, or including, the radiation-shielding material, the walls 102 may be joined to one another proximate vertexes 108 of the container 100 utilizing a stair-step configuration. For example, innermost sheets 106 may have a smallest longitudinal length 112, and the longitudinal length 112 of each successive sheet 106 as distance to the exterior decreases may be progressively greater, forming a stair-step shape at a periphery of the wall 102. The stair-step-shaped peripheries of walls 102 oriented perpendicular to one another may be brought into mating contact with one another, forming the associated vertex 108. Adjacent walls 102 may be secured to one another, and adjacent sheets 106 of a given wall 102 may be secured to one another, utilizing a mechanical connector (e.g., nails, screws, bolts), adhesive material (e.g., glue, epoxy), mechanical interference (e.g., a snap fit, a friction fit), or other suitable connection. In some embodiments, a sealing member (e.g., an elastomeric sealing ring) may be positioned between adjacent walls 102 to form or improve the quality of a seal between the walls 102.

At least a portion of at least one of the walls 102 may be displaceable to enable a user to selectively access an interior of the container 100. For example, one of the walls 102 may be removable, rotatable, or otherwise displaceable with respect to the other walls 102 to enable a user to access the interior volume 104 of the container 100 and to subsequently close the container 100 to at least partially restrict access to the interior volume 104 of the container 100. More specifically, one of the walls 102 (e.g., the top wall 102 when the container 100 is supported on a floor) may form a lid that is removable entirely or is hinged to an adjacent wall 102 to grant selective access to the interior volume 104 of the container 100. As another example, a portion of one of the walls 102 may be removable, rotatable, or otherwise displaceable with respect to the remainder of that wall 102, and to the other walls 102, to enable a user to access the interior volume 104 of the container 100 and to subsequently close the container 100 to at least partially restrict access to the interior volume 104 of the container 100. More specifically, one or more of the walls 102 may include an opening 116 extending through a portion of the wall 102 and a plug 114 to selectively obstruct the opening 116. As a specific, nonlimiting example, one of the walls 102 may include a plug 114 configured as a door having a wall 102 and a hinge 118, enabling a user to selectively displace the plug 114 from within the opening 116 to access the interior volume 104 and to replace the plug 114 into the opening 116 to place the container 100 in a closed state. The wall 102, portion of the wall 102, or plug 114 may be securable in place relative to a remainder of the container 100 (e.g., utilizing a latch, a snap fit, a pin, etc. and optionally including a sealing member to form a seal) to temporarily fix the container 100 in the closed state.

The container 100 may be sized, shaped, and configured to support one or more semiconductor devices configured as semiconductor wafers, semiconductor device packages, or a substrates supporting one or more semiconductor device packages therein. The size and shape of the container 100, as well as the size and shape of the interior volume 104 and any access openings for the container 100, may be adapted for the desired application for the container 100.

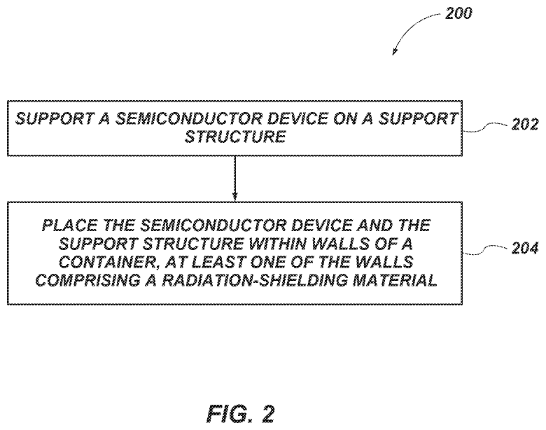

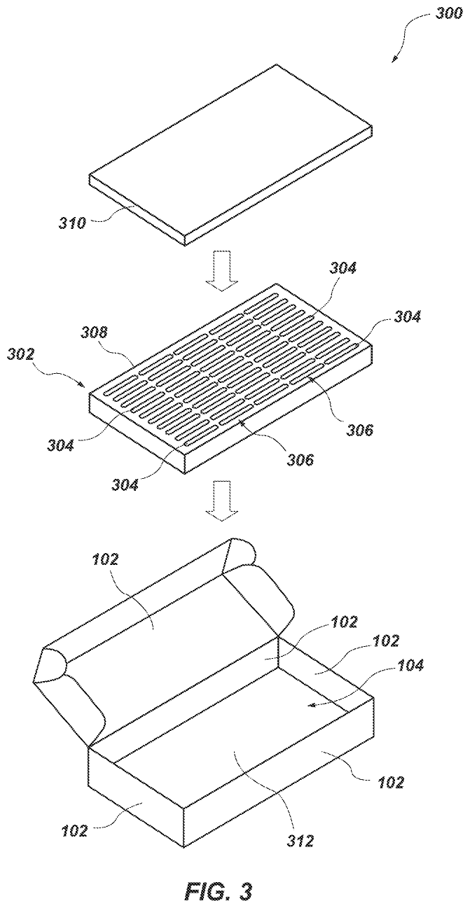

FIG. 2 is a flowchart of a method 200 of protecting one or more semiconductor devices utilizing a container in accordance with this disclosure. FIG. 3 is an exploded view of another embodiment of a container 300 including a support structure 302 for supporting semiconductor devices 304 within the container 300. With combined reference to FIG. 2 and FIG. 3, the method 200 may involve supporting a semiconductor device 304 on a support structure 302, as indicated at act 202. The support structure 302 may be sized, shaped, positioned, and configured to support each respective semiconductor device 304 within the walls 102 of the container 300. For example, the support structure 302 may be a tray, rack, shell, foam cell divider, or a combination thereof, and may include slots 306, slits, recesses, voids, shelves, compartments, other receptacles, or a combination thereof into which the semiconductor devices 304 may be received. In the embodiment specifically depicted in FIG. 3, the support structure 302 may include a body 308 configured as a foam cell divider having slots 306 into which the semiconductor device 304 may be inserted, and friction between the resilient foam material of the support structure 302 and contacting surfaces of the semiconductor device 304 may be used to retain the semiconductor device 304 in the slot 306. The support structure 302 may also include a lid 310 and a floor 312 positionable over and under major surfaces of the body 308, and over and under the slots 306 and semiconductor devices 304 therein. The lid 310 and floor 312 may provide additional protection and security for the semiconductor devices 304, may reduce the likelihood that the semiconductor devices 304 would exit the slots 306 while the support structure 302 is in the container 300, and may be receivable in the interior volume 104 of the container 300 along with the body 308.

The support structure 302 may be adapted to support semiconductor devices 304 having different form factors, depending on the intended application for the container 300. For example, the support structure 302 may be sized, shaped, and configured to support a semiconductor device configured as a semiconductor die, a semiconductor device package, or a module comprising a substrate supporting one or more semiconductor device packages thereon. In the embodiment of FIG. 3, the slots 306 in the body 308 of the support structure 302 may be sized, shaped, and configured to receive semiconductor devices 304 in the form of a substrate supporting one or more semiconductor device packages thereon. More specifically, the slots 306 in the body 308 of the support structure 302 may be sized, shaped, and configured to receive individual memory devices (e.g., dynamic random access memory (DRAM) devices, solid state drives) conforming to a standardized form factor (e.g., dual in-line memory modules (DIMMs), 2.5-inch drives, 3.5-inch drives, M.2 modules) in the slots 306.

The method 200 may also involve placing the semiconductor devices 304 and the support structure 302 within the walls 102 of the container 300, as indicated at act 204. At least one of the walls 102 may include a radiation-shielding material, as discussed previously in connection with FIG. 1, and as also indicated at act 204. The container 300 may then be used to protect the semiconductor device 304 from at least certain forms of radiation in desired situations. For example, the container 300 may be used to inhibit neutron and/or proton radiation from altering a state of a silicon latter in the semiconductor devices 304 utilizing the radiation-shielding material of the walls 102. More specifically, the container 300 may be used to reduce the likelihood that damage will be induced by environmental radiation impacting a semiconductor device 304 (e.g., that a bit of a memory device of a given semiconductor device 304 within the walls 102 will flip, that radiation will alter current-voltage characteristics of trench FET commercial power MOSFETS) utilizing the radiation-shielding material.

As a summary, containers for supporting one or more semiconductor devices therein in accordance with some embodiments may include walls positioned to at least partially surround a semiconductor device. At least one of the walls may include a radiation-shielding material. A support structure may be shaped, positioned, and configured to support the semiconductor device within the walls.

In other embodiments, methods of protecting one or more semiconductor devices may involve supporting a semiconductor device on a support structure. The semiconductor device and the support structure may be placed within walls of a container. At least one of the container walls may include a radiation-shielding material.

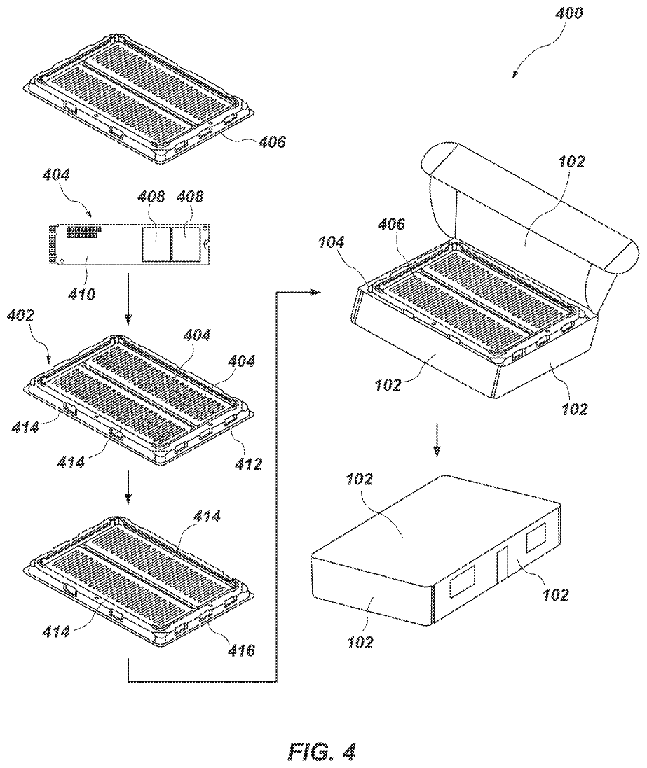

FIG. 4 is an exploded view of another embodiment of a container 400 including another embodiment of a support structure 402 for supporting semiconductor devices 404 within the container 400. The support structure 402 of FIG. 4 may be configured as, for example, a tray 412 having a lid 406 (or shell), and may include compartments 414 or other receptacles into which the semiconductor devices 304 may be received. More specifically, the support structure 402 may include a tray 412 configured as a rigid or semi-rigid, polymeric shell (e.g., a blister pack) having compartments 414 into which the semiconductor devices 404 may be inserted, and gravity, mechanical interference with stacked trays 412, and/or a lid 406 may be used to retain the semiconductor devices 404 in the compartments 414. The lid 406 and stackability of the trays 412 may provide additional protection and security for the semiconductor devices 404, may reduce the likelihood that the semiconductor devices 404 would exit the compartments 414 while the support structure 402 is in the container 400, and may be receivable in a stacked state in the interior volume 104 of the container 400.

The semiconductor devices 404 of FIG. 4 may be configured as, for example, a substrate 410 (e.g., a printed circuit board (PCB)) supporting one or more semiconductor device packages 408 thereon. More specifically, the compartments 414 in the trays 412 of the support structure 402 may be sized, shaped, and configured to receive individual memory devices (e.g., dynamic random access memory (DRAM) devices, solid state drives) conforming to a standardized form factor (e.g., dual in-line memory modules (DIMMs), 2.5-inch drives, 3.5-inch drives, M.2 modules) compartments 414.

The container 400 may be used to protect the semiconductor devices 404 from at least certain forms of radiation in desired situations, such as, for example, during shipping, short-term storage, and/or long-term storage. For example, the container 400 may be used to inhibit neutron and/or proton radiation from altering a state of a silicon latter in the semiconductor devices 404 utilizing the radiation-shielding material of the walls 102. More specifically, the container 400 may be used to reduce the likelihood that radiation from outside the container 400 will induce damage in a given semiconductor device 404 (e.g., that a bit of a memory device of a given semiconductor device 404 will flip, that radiation will induce alterations of current-voltage characteristics of trench FET commercial power MOSFETS) within the walls 102 utilizing the radiation-shielding material.

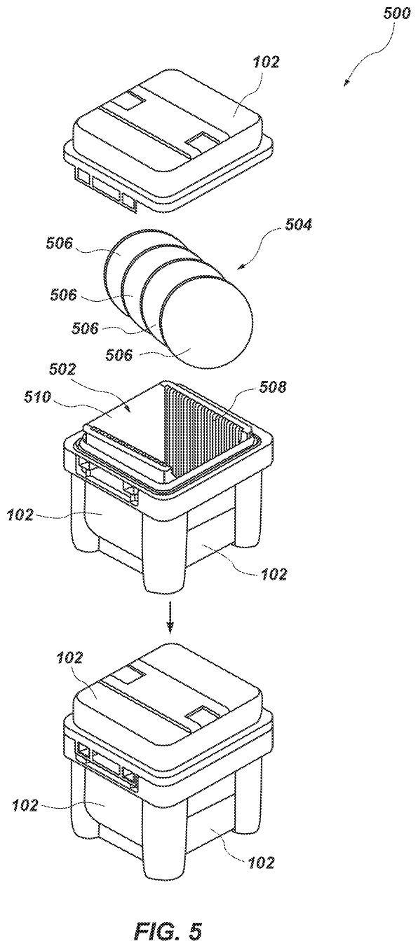

FIG. 5 is an exploded view of another embodiment of a container 500 including another embodiment of a support structure 502 for supporting semiconductor devices 504 within the container 500. The support structure 502 of FIG. 5 may be configured as, for example, a rack 510 having slits 508 or other receptacles into which at least portions of the semiconductor devices 504 may be received. More specifically, the support structure 502 may include a rack 510 configured as a rigid or semi-rigid, polymeric frame having slits 508 in its sidewalls into which the semiconductor devices 404 may be inserted, and gravity, mechanical interference with the rack 510, and/or a lid formed from one of the walls 102 of the container 500 may be used to retain the semiconductor devices 504 in the slits 508. In some embodiments, the container 500 may be configured as a standard mechanical interface (SMIF) pod or a front opening unified pod (FOUP), may be loaded with the semiconductor devices 504 in a controlled environment (e.g., a cleanroom of a semiconductor fabrication facility), and may maintain the semiconductor devices 504 in a controlled environment to reduce the likelihood of contamination.

The semiconductor devices 504 of FIG. 5 may be configured as, for example, device regions of semiconductor wafers 506. More specifically, the slits 508 in the rack 510 of the support structure 502 may be sized, shaped, and configured to receive edges of individual semiconductor wafers 506 having integrated circuitry configured as memory devices (e.g., dynamic random access memory (DRAM) devices, solid state drives) in or on device regions of a major surface of the respective semiconductor wafer 506 and between streets lacking such integrated circuitry.

The container 500 may be used to protect the semiconductor devices 504 from at least certain forms of radiation in desired situations, such as, for example, during shipping, short-term storage, and/or long-term storage. For example, the container 500 may be used to inhibit neutron and/or proton radiation from altering a state of a silicon latter in the semiconductor devices 504 utilizing the radiation-shielding material of the walls 102. More specifically, the container 500 may be used to reduce the likelihood that radiation from outside the container 500 will damage a given semiconductor wafer 506 (e.g., that a bit of a memory device of a given semiconductor wafer 506, that radiation will alter current-voltage characteristics of trench FET commercial power MOSFETS) within the walls 102 utilizing the radiation-shielding material.

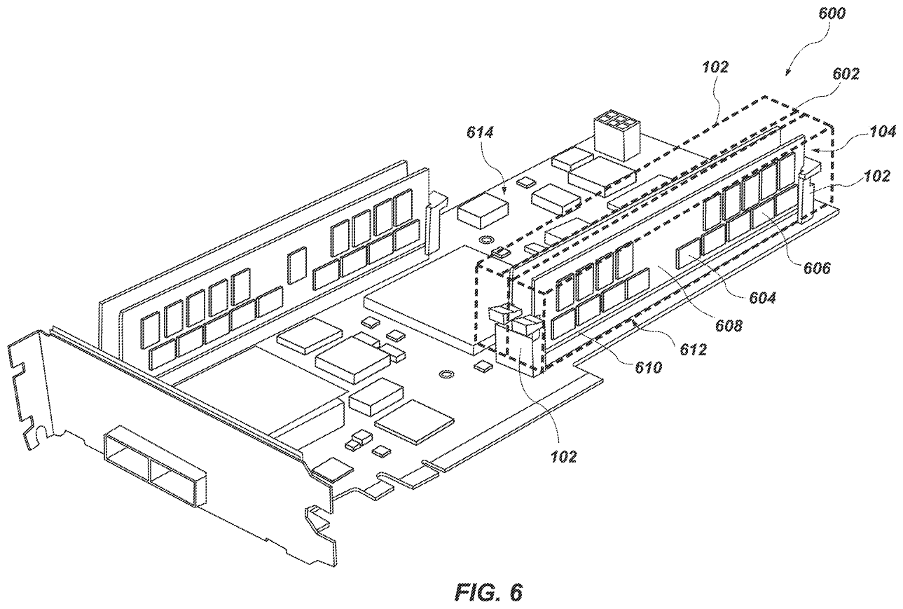

FIG. 6 is a side perspective, transparent view of another embodiment of a container 600 for protecting one or more semiconductor devices 606 therein. In some embodiments, the container 600 may be sized, shaped, and configured to protect the semiconductor devices 606 when the semiconductor devices 606 are in an installed state. For example, the container 600 may include a port 612, slot, or cutout in one or more walls 102 of the container 600, enabling a portion of each semiconductor device 606 located partially therein to extend from the interior volume 104 to the exterior of the container 600. More specifically, an interface portion of each semiconductor device 606 located partially in the container 600 may be engaged with an associated socket 610 (e.g., a DIMM socket, a peripheral component interconnect express (PCIE) socket, an M.2 slot), and a remainder of the substrate 608 of the semiconductor device 606 may be located within the container 600.

The container 600 may be configured as, for example, a case for positioning around a majority of the semiconductor device 606 after the semiconductor device 606 has been installed (e.g., a PC case). For example, the container 600 may include two clamshell portions rotatable with respect to one another about a hinge 602 and a latch (e.g., a snap-fit, a pinned connection) to secure the clamshell portions to one another on a side opposite the hinge 602 when the container 600 is in a closed state.

To install the semiconductor device 606 and the container 600, the semiconductor device 606 may first be installed into the relevant socket 610, connecting the semiconductor device 606 to another system 614 (e.g., a motherboard, an expansion card). The container 600 may then be installed around the semiconductor device 606, with a connector portion of the semiconductor device 606 extending through the port 612 in the container 600 for communication with higher level packaging exterior to the container, and a remainder of the semiconductor device 606 being located within the interior volume 104 of the container 600.

The container 600 may be used to protect the semiconductor devices 606 from at least certain forms of radiation in desired situations, such as, for example, after installation and during operation. For example, the container 600 may be used to inhibit neutron and/or proton radiation from altering a state of a silicon latter in the semiconductor devices 606 utilizing the radiation-shielding material of the walls 102. More specifically, the container 600 may be used to reduce the likelihood that radiation from outside the container 600 will damage a given semiconductor device 606 (e.g., that a bit of a memory device of a given semiconductor device 606 will flip, that radiation will alter current-voltage characteristics of trench FET commercial power MOSFETS) within the walls 102 utilizing the radiation-shielding material.

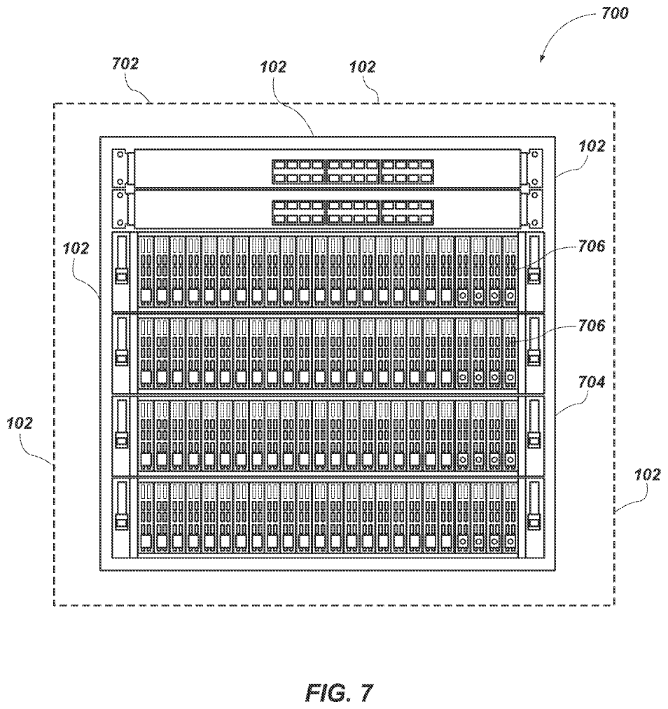

FIG. 7 is a front view of another embodiment of a container 700 for supporting one or more semiconductor devices 706 therein. For example, the container 700 may be configured to support a group of semiconductor devices 706 in installed states. More specifically, the container 700 may be configured as a housing for containing computing components (e.g., a computer case, a server rack 704) or a building 702 for temporarily storing or storing computing components for the long term (e.g., a warehouse, a retail store, a server site). In such a configuration, the radiation-shielding material of the walls 102 may be integrated into surfaces of the housing (e.g., sidewalls, a cover for the server rack 704) or into building materials of the building 702 (e.g., walls, floor, ceiling).

The semiconductor devices 706 may be configured as, for example, hot-swappable components for deployment in server racks 704. More specifically, the semiconductor devices 706 may be configured as hot-swappable memory devices for deployment in server racks 704.

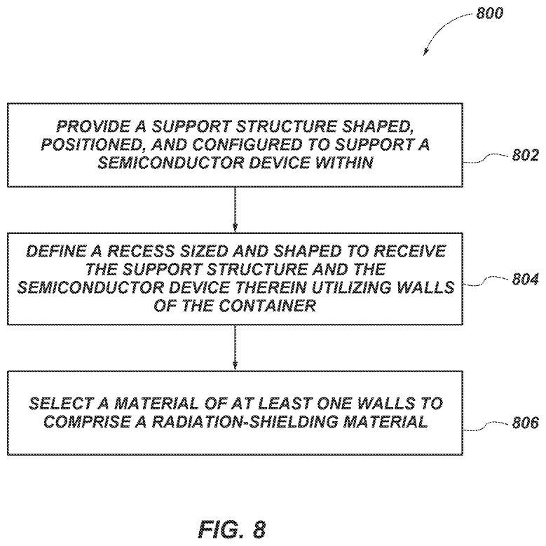

FIG. 8 is a flowchart of a method 800 of making a container for supporting one or more semiconductor devices therein. The method 800 may involve, for example, providing a support structure shaped, positioned, and configured to support a semiconductor device within, as indicated at act 802. A recess sized and shaped to receive the support structure and the semiconductor device therein may be defined utilizing walls of the container, as shown at act 804. A material of at least one walls may be selected to include a radiation-shielding material, as indicated at act 806.

In some embodiments, the radiation-shielding material may be selected to reduce the likelihood that neutron radiation will alter a state of a silicon lattice in the semiconductor device. For example, the radiation-shielding material may be selected to include at least one material selected from the group consisting of borated polyethylene, boron carbide, and a boron aluminum alloy, or any of the other materials described previously in connection with FIG. 1.

In some embodiments, defining the recess utilizing the walls may involve layering sheets of the radiation-shielding material in layers to form at least a portion of the at least one of the walls, as described in connection with FIG. 1. In some embodiments, each of the walls may include the radiation-shielding material. In other embodiments, at least one of the walls may lack the radiation-shielding material. For example, the wall positioned and configured to face a floor when the container is placed on a floor may be free of the radiation-shielding material.

In summary, methods of making containers for supporting one or more semiconductor devices therein may involve providing a support structure shaped, positioned, and configured to support a semiconductor device. A recess sized and shaped to receive the support structure and the semiconductor device may be defined therein utilizing walls of the container. A material of at least one walls may be selected to include a radiation-shielding material.

Embodiments of containers in accordance with this may reduce the likelihood that at least some types of radiation may otherwise produce deleterious effects in semiconductor devices, such as, for example, bit flipping in memory devices and/or radiation-induced alteration of current-voltage characteristics of trench FET commercial power MOSFETS. Such containers may be particularly useful in situations where radiation is more likely to be encountered, such as, for example, when shipping by air, in aerospace applications (e.g., black boxes, control systems), at high altitudes, and in nuclear facilities. Such containers may also find application in situations where reliability is important, such as, for example, in autonomous control systems implicating the safety of humans (e.g., self-driving cars, autopilots for airplanes, autopilots for other aerospace systems, defense systems) and voting systems. Radiation-shielding containers in accordance with this disclosure may also reduce the need to re-test and verify the functionality of semiconductor devices after shipping and after spending time in storage.

While certain illustrative embodiments have been described in connection with the figures, those of ordinary skill in the art will recognize and appreciate that the scope of this disclosure is not limited to those embodiments explicitly shown and described in this disclosure. Rather, many additions, deletions, and modifications to the embodiments described in this disclosure may be made to produce embodiments within the scope of this disclosure, such as those specifically claimed, including legal equivalents. In addition, features from one disclosed embodiment may be combined with features of another disclosed embodiment while still being within the scope of this disclosure.

What is claimed is:

1. A container for supporting one or more semiconductor devices therein, comprising:
walls positioned to at least partially surround a semiconductor device, at least one of the walls comprising a radiation-shielding material; and
a support structure shaped, positioned, and configured to support the semiconductor device within the walls.

2. The container of claim 1, wherein the radiation-shielding material is configured to reduce the likelihood that neutron radiation from an ambient environment exterior to the container will alter a state of a silicon lattice in the semiconductor device.

3. The container of claim 1, wherein the radiation-shielding material comprises at least one material selected from the group consisting of borated polyethylene, boron carbide, and a boron aluminum alloy.

4. The container of claim 1, wherein the support structure is sized, shaped, and configured to support a semiconductor device configured as a semiconductor die, a semiconductor wafer, a semiconductor device package, or a substrate supporting one or more semiconductor device packages thereon.

5. The container of claim 1, wherein the at least one of the container walls comprises sheets of the radiation-shielding material in superimposed layers to form at least a portion of the at least one of the walls.

6. The container of claim 1, wherein each of the container walls comprises the radiation-shielding material.

7. The container of claim 1, wherein at least another of the container walls lacking the radiation-shielding material is positioned and configured to face a floor when the container is placed on a floor.

8. The container of claim 1, further comprising at least one port in one or more of the walls of the container, wherein a connector portion of the semiconductor device extends through the at least one port when a remainder of the semiconductor device is located within the container to enable the semiconductor device to be connected to higher-level packaging.

9. The container of claim 1, wherein at least a portion of at least one of the container walls is displaceable to enable a user to selectively access an interior of the container.

10. The container of claim 1, wherein the support structure comprises a tray, rack, shell, foam cell divider, or a combination thereof, and comprises slots, slits, recesses, voids, shelves, compartments, or a combination thereof sized, shaped, positioned, and configured to receive the semiconductor device.

11. A method of protecting one or more semiconductor devices, comprising:
supporting a semiconductor device on a support structure; and
placing the semiconductor device and the support structure within walls of a container, at least one of the container walls comprising a radiation-shielding material.

12. The method of claim 11, further comprising inhibiting neutron radiation from an ambient environment exterior to the container from altering a state of a silicon lattice in the semiconductor device utilizing the radiation-shielding material.

13. The method of claim 11, wherein the semiconductor device includes memory and further comprising reducing the likelihood that a bit of the memory will flip utilizing the radiation-shielding material.

14. The method of claim 11, wherein supporting the semiconductor device utilizing the support structure comprises supporting a semiconductor die, a semiconductor wafer, a semiconductor device package, or a substrate supporting one or more semiconductor device packages thereon utilizing the support structure.

15. The method of claim 14, wherein supporting the semiconductor device utilizing the support structure comprises supporting a substrate supporting one or more semiconductor device packages thereon, and wherein the one or more semiconductor device packages are configured as dynamic random access memory devices.

16. A method of making a container for supporting one or more semiconductor devices therein, comprising:
providing a support structure shaped, positioned, and configured to support a semiconductor device;
defining a recess sized and shaped to receive at least a portion of the support structure and the semiconductor device therein utilizing walls of the container; and
selecting a material of one or more container walls to comprise a radiation-shielding material.

17. The method of claim 16, further comprising selecting the radiation-shielding material to reduce the likelihood that neutron radiation will impinge upon a silicon lattice in the semiconductor device.

18. The method of claim 16, further comprising selecting the radiation-shielding material comprises at least one material selected from the group consisting of borated polyethylene, boron carbide, and a boron aluminum alloy.

19. The method of claim 16, wherein defining the recess utilizing the walls comprises layering sheets of the radiation-shielding material in mutual superimposition to form at least a portion of the at least one of the walls.

20. The method of claim 16, further comprising selecting the material of each of the container walls to comprise the radiation-shielding material.

21. The method of claim 16, further comprising selecting the material of one of the container walls to lack the radiation-shielding material, the one of the container walls positioned and configured to face a floor when the container is placed on a floor.
